(19) United States
(12) Patent Application Publication
(10) Pub. No.: US 2026/0031769 A1
(43) Pub. Date: Jan. 29, 2026

(54) INTERSTAGE BIASING WITH BREAKDOWN PROTECTION

(71) Applicant: MACOM Technology Solutions Holdings, Inc., Lowell, MA (US)

(72) Inventors: Ariel L. Vera Villarroel, Lake Oswego, OR (US); Abdelrahman H. Ahmed, Portland, OR (US)

(21) Appl. No.: 18/780,901

(22) Filed: Jul. 23, 2024

(51) Int. Cl. H03F 1/52; H03F 3/45

(52) U.S. Cl. CPC H03F 1/52; H03F 3/45475; H03F 2200/426

(57) ABSTRACT

Amplifiers incorporating input biasing and breakdown protection circuits are described. An example amplifier circuit with input biasing and breakdown protection includes an amplifier having an input and an output, a bias circuit coupled between the input and the output of the amplifier, and a breakdown protection circuit coupled to a common terminal of the amplifier. The breakdown protection circuit is configured to maintain a potential difference across the common terminal and the output of the amplifier based on a reference potential over a voltage supply range for the amplifier circuit. The bias circuit is configured to adjust a bias potential at the input of the amplifier with closed loop control based on the output of the amplifier.

### BACKGROUND

A range of different amplifiers are known and relied upon for data communications. Differential amplifiers, as an example, are commonly used for high-speed data communications. Differential amplifiers are designed to amplify the difference between two input signals and to reject noise or interference that is present on both (i.e., common to) the input signals. Differential amplifiers are often used as the first amplifier stage in operational amplifiers, and multiple stages of differential amplifiers can be cascaded depending on design needs and the amplification application. Each amplifier stage can have a different amplifier configuration.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

An example amplifier circuit with input biasing and breakdown protection includes an amplifier with an input and an output, a bias circuit coupled between the input and the output of the amplifier, and a breakdown protection circuit coupled to a common terminal of the amplifier other than the input or the output. The breakdown protection circuit is configured to maintain a potential difference across the common terminal and the output of the amplifier based on a reference potential in some aspects and embodiments.

In some examples, the amplifier includes a pair of common collector transistors, and the breakdown protection circuit is coupled to collector terminals of the pair of common collector transistors. The breakdown protection circuit can include a reference voltage generator, a level shifter, and a regulator follower in some cases.

In other aspects, the bias circuit can be configured to adjust a bias potential at the input of the amplifier with closed loop control based on the output of the amplifier. The bias circuit can adjust a bias potential at the input of the amplifier for direct current interstage coupling in a multi-stage amplifier, and other applications for the bias circuit are described. The amplifier circuit can also include an isolation impedance coupled between a preceding amplifier stage in the multi-stage amplifier and the input of the amplifier. The isolation impedance can include a parallel combination of a resistor and a capacitor in one example.

Another example amplifier circuit includes an amplifier with a pair of common collector transistors, an input, and an output, a bias circuit coupled between the input and the output of the amplifier, and a breakdown protection circuit coupled to a common terminal of the amplifier other than the input or the output.

An example biasing and breakdown protection circuit includes a bias circuit coupled between an input and an output of the amplifier, and a breakdown protection circuit configured to maintain a potential difference across terminals of the amplifier based on a reference potential.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example multi-stage amplifier according to various examples described herein.

FIG. 2 illustrates an example amplifier circuit with input biasing and breakdown protection according to various examples described herein.

FIG. 3 illustrates an example amplifier circuit with input biasing and breakdown protection according to various examples described herein.

### DETAILED DESCRIPTION

Receivers, transmitters, and transceivers for emerging data communication applications rely upon amplifier circuits to transfer data signals at higher speeds. The amplifier circuits are often designed for broadband operation and minimal power consumption to the extent possible. Differential amplifiers are commonly used for high-speed data communications. Multiple stages of differential amplifiers can be cascaded or connected in series depending on the design needs of a given amplifier application. It can be important to tailor and optimize the operating criteria and performance of each amplifier stage in a multi-stage amplifier. Often, the quiescent operating point of a given amplifier stage will not match or align with the preceding or following stage in a multi-stage amplifier, and intervening or intermediary circuits are needed for bias shifting and other purposes.

Amplifiers incorporating input biasing and breakdown protection circuits are described. An example amplifier circuit with input biasing and breakdown protection includes an amplifier having an input and an output, a bias circuit coupled between the input and the output of the amplifier, and a breakdown protection circuit coupled to a common terminal of the amplifier. The breakdown protection circuit is configured to maintain a potential difference across the common terminal and the output of the amplifier based on a reference potential over a voltage supply range for the amplifier circuit. The bias offset correction circuit is configured to adjust a bias potential at the input of the amplifier with closed loop control based on the output of the amplifier.

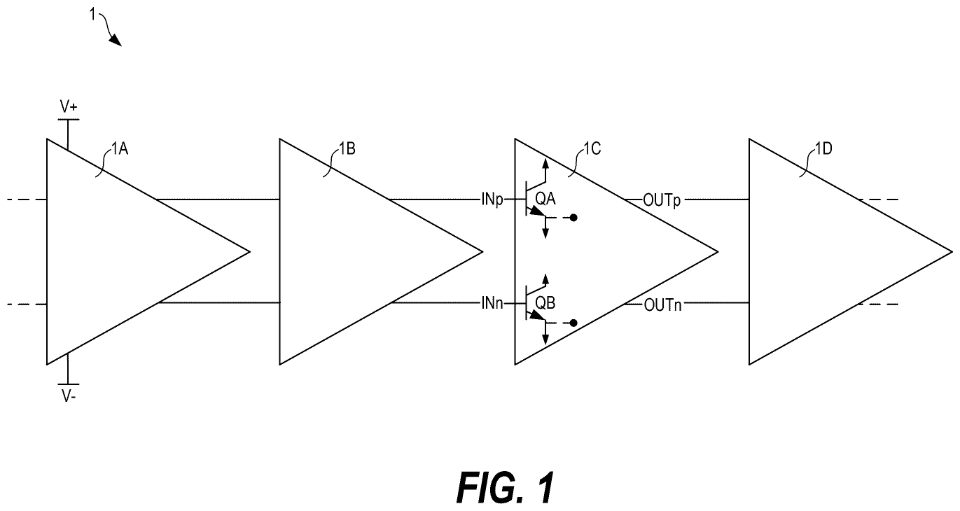

FIG. 1 illustrates an example multi-stage amplifier 1 according to various examples described herein. The multi-stage amplifier 1 can be embodied in various ways, such as using discrete components, as an integrated circuit device formed on a substrate, or as a combination of discrete components and integrated devices. The multi-stage amplifier 1 is depicted as a representative example. The multi-stage amplifier 1 is not exhaustively illustrated in FIG. 1, and the multi-stage amplifier 1 can include additional components that are not shown.

The multi-stage amplifier 1 includes a number of cascaded amplifier circuits or stages, including amplifier stages 1A-1D, among possibly others. In the cascaded configuration shown, the outputs of the amplifier stage 1A are provided as inputs to the amplifier stage 1B. The outputs of the amplifier stage 1B are provided as inputs to the amplifier stage 1C, and so on. Multi-stage amplifiers can be relied upon for increased overall gain over a broad, to tailor input or output impedances, or to achieve other objectives. Each of the amplifier stages 1A-1D is supplied with power by an upper rail voltage or potential V+ and a lower rail voltage or potential V−.

Each of the amplifier stages 1A-1D can include one or more transistor amplifiers, biasing circuitry, coupling circuitry, and related circuit components. Additionally, the transistor or transistors in each of the amplifier stages 1A-1D can be arranged or configured in different ways (e.g., differential pair, Darlington pair, common collector or drain, common emitter or source, or common base or gate, etc.) depending on the design, objectives, and application for the multi-stage amplifier 1. The amplifier stage 1C is shown to include two common collector transistors QA and QB, as an example, for handling a differential signal.

Each of the amplifier stages 1A-1D can be designed, tailored, and optimized independently. Beyond the design of each of the amplifier stages 1A-1D, the interconnections among them can also be a design concern. AC coupling with capacitors among the amplifier stages 1A-1D can be unsuitable or undesirable due to lack of available space in integrated solutions, parasitic and operating bandwidth concerns, or other issues. At the same time, the quiescent operating point of a given amplifier stage 1A-1D may not match or align with the preceding or following stage in the multi-stage amplifier 1. For example, DC biasing levels of the output signal from the amplifier stage 1B can be mismatched for the quiescent operating point of the amplifier stage 1C. Interstage biasing solutions capable of adjusting DC biasing levels among the amplifier stages 1A-1D can be important to overcome such mismatches. The solutions should provide proper biasing without impacting the overall performance or reliability of the amplifier stages 1A-1D or the transistors in the amplifier stages 1A-1D.

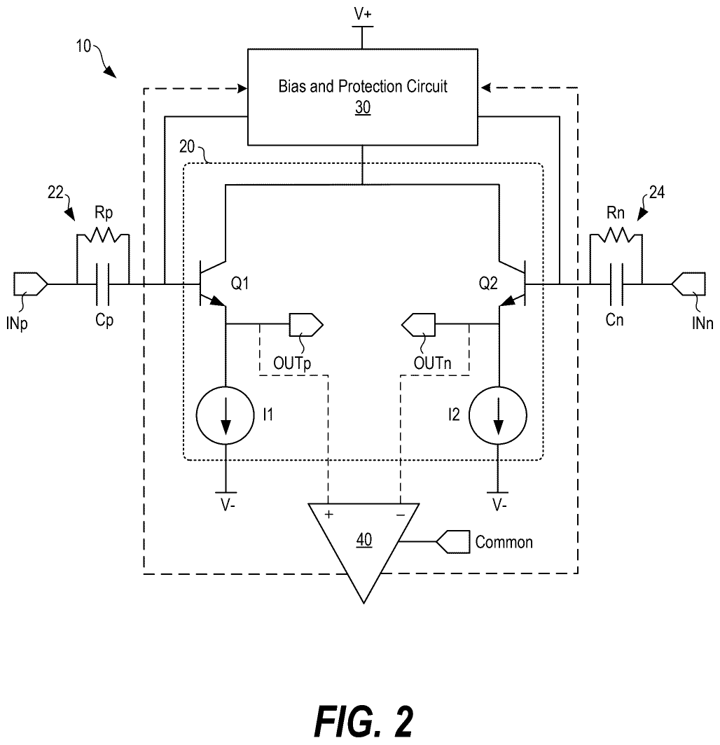

FIG. 2 illustrates an example amplifier circuit 10 with input biasing and breakdown protection according to various examples described herein. The amplifier circuit 10 can be embodied in various ways, such as using discrete components, as an integrated circuit device formed on a substrate, or as a combination of discrete components and integrated devices. The amplifier circuit 10 is provided as a representative example of an amplifier stage with interstage biasing and breakdown protection. The amplifier circuit 10 is not exhaustively illustrated in FIG. 2, and the amplifier circuit 10 can include additional components that are not shown. The amplifier circuit 10 can also omit certain components in some cases.

The amplifier circuit 10 includes an amplifier or amplifier stage 20 (also “amplifier 20”), a bias and protection circuit 30 (also “bias circuit 30”), and a differential operational amplifier 40 (also “differential amplifier 40”), among possibly other components. The differential amplifier 40 can be considered a part or component of the bias circuit 30. The amplifier 20 can be used as an amplifier stage for radio frequency (RF) communications, wired communications, optical communications, or for other purposes, without limitation. The amplifier 20 can also be an amplifier stage in a multi-stage amplifier, such as the multi-stage amplifier 1 in FIG. 1. The bias circuit 30 is coupled to inputs and common terminals of the amplifier 20 and receives control signals from the differential amplifier 40, as described in further detail below.

The amplifier 20 includes two transistors Q1 and Q2 and two current sources I1 and I2. The transistors Q1 and Q2 are depicted as bipolar junction transistors in FIG. 2. However, the transistors Q1 and Q2 can be embodied as field effect transistors (FETs), and the concepts described herein are not limited to use with amplifiers or transistors of any particular type or technology. The transistors Q1 and Q2 are configured as common collectors in the example shown in FIG. 2, although other types and configurations of amplifiers and amplifier circuits can also incorporate the biasing adjustment and breakdown protection concepts described herein.

The collectors of the transistors Q1 and Q2 are coupled together and to the upper rail voltage or potential V+ through the bias circuit 30. The bias circuit 30 includes a breakdown protection circuit configured to maintain a steady and regulated input voltage for the transistors Q1 and Q2 over a voltage supply range for the amplifier circuit 10. An output OUTp (e.g., positive or non-inverting output) of the amplifier 20 can be taken from the emitter of the transistor Q1. The base of the transistor Q1 operates as an input INp (e.g., positive or non-inverting input) of the amplifier 20. The emitter of the transistor Q1 is coupled to the current source I1. The current source I1 is coupled between the emitter of the transistor Q1 and the lower rail voltage or potential V−, which can be ground potential in some cases.

An output OUTn (e.g., negative or inverting output) of the amplifier 20 can be taken from the emitter of the transistor Q2. The base of the transistor Q2 operates as another input INn (e.g., negative or inverting input) of the amplifier 20. The emitter of the transistor Q2 is coupled to the current source I2. The current source I2 is coupled between the emitter of the transistor Q2 and the lower rail voltage or potential V−, which can be ground potential in some cases.

The amplifier circuit 10 also includes a first isolation impedance 22 at the INp input and a second isolation impedance 24 at the INn input. The first isolation impedance 22 includes the resistor Rp and the capacitor Cp, which are coupled in parallel. The first isolation impedance 22 is coupled between the INp input and the base terminal of the transistor Q1. The second isolation impedance 24 includes the resistor Rn and the capacitor Cn, which are also coupled in parallel. The second isolation impedance 24 is coupled between the INn input and the base terminal of the transistor Q2. The first and second isolation impedances 22 and 24 are described in further detail below.

The amplifier 20 can be an amplifier stage among several stages in a multi-stage amplifier. The bias and protection circuit 30 is coupled to the INp and INn inputs of the amplifier 20 as shown in FIG. 2. The bias and protection circuit 30 is also intermediate between the upper rail voltage V+ and the collectors or common terminals of the transistors Q1 and Q2. The bias circuit 30 includes components for multiple purposes, including circuit components for bias adjustments to the base terminals of the transistors Q1 and Q2 and circuit components for breakdown (e.g., overvoltage) protection for the transistors Q1 and Q2.

The bias circuit 30 is configured to alter or modify the bias potentials (e.g., DC bias potentials) of the input signals provided to the INp and INn inputs. More particularly, the bias circuit 30 can alter or modify the bias potentials of the input signals between the first and second isolation impedances 22 and 24 and the base terminal inputs of the transistors Q1 and Q2. The bias circuit 30 is configured to adjust the bias potentials at the base terminal inputs of the transistors Q1 and Q2 with closed loop control based on control signals from the differential amplifier 40.

The breakdown protection circuit in the bias circuit 30 is configured to maintain the potential difference across the common terminals and the outputs of the transistors Q1 and Q2 to within a certain specification or limit, even over range of supply voltages applied to the amplifier circuit 10, to protect the transistors Q1 and Q2. In other words, the breakdown protection circuit in the bias circuit 30 is configured to maintain the collector to emitter voltage potential difference to within or below the breakdown voltage (i.e., the V_{CE} breakdown voltage) for the transistors Q1 and Q2. These and other aspects of the bias circuit 30 are described in further detail below.

The amplifier circuit 10 is not exhaustively illustrated in FIG. 1, and the amplifier circuit 10 can include additional components that are not shown. For example, one or more resistors or other circuit components can be coupled between the transistors Q1 and Q2 and the bias circuit 30, between the emitters of the transistors Q1 and Q2 and the lower rail voltage V−, and at other locations. Coupling, blocking, and other capacitors can also be relied upon as would be understood in the field.

The current sources I1 and I2 are representative in FIG. 2, and each can be implemented as any suitable type of current source or related biasing circuitry for the transistors Q1 and Q2. Examples of the current sources I1 and I2 include transistor-based current mirrors, current regulators, resistors, and combinations thereof, but the current sources I1 and 12 are not limited to any particular type of implementation. The current sources I1 and I2 can also be implemented or embodied as variable current sources in some cases.

The upper rail voltage V+ can be any suitable voltage, and the lower rail voltage V− can be any suitable voltage or potential (e.g., including ground potential in some cases) that is less than the upper rail voltage V+. The voltages V+ and V− can be selected, respectively, based on the target biasing voltage or voltage range for the amplifier circuit 10. The difference in potential between the voltages V+ and V− can be any suitable potential difference based on the target biasing voltage or voltage range for the amplifier circuit 10.

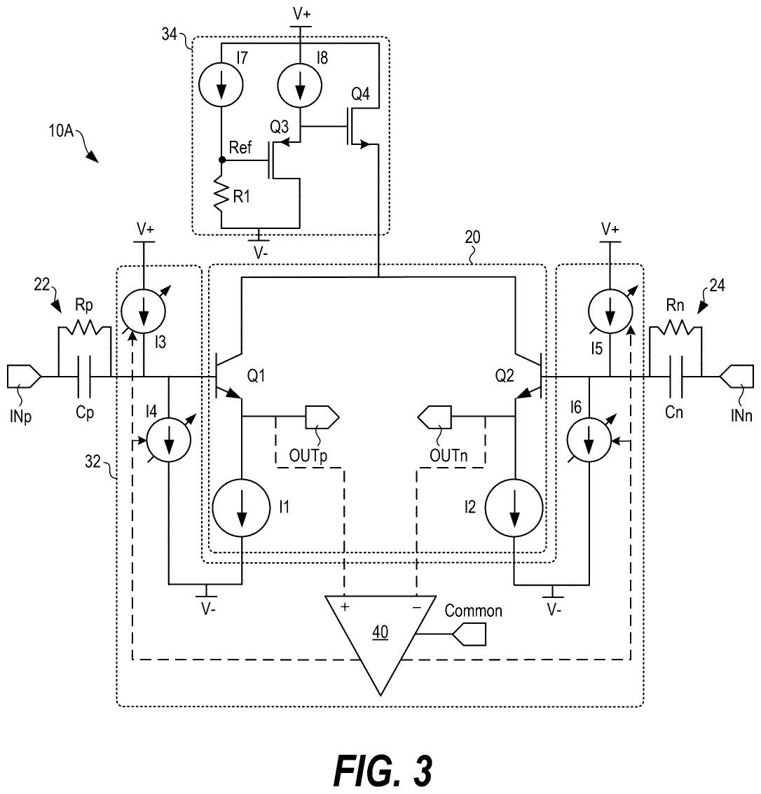

FIG. 3 illustrates an example amplifier circuit 10A with input biasing and breakdown protection according to various examples described herein. The amplifier circuit 10A can be embodied in various ways, such as using discrete components, as an integrated circuit device formed on a substrate, or as a combination of discrete components and integrated devices. The amplifier circuit 10A is provided as a representative example of an amplifier stage with interstage biasing and breakdown protection. The amplifier circuit 10A is not exhaustively illustrated in FIG. 3, and the amplifier circuit 10A can include additional components that are not shown. The amplifier circuit 10A can also omit certain components in some cases.

The amplifier circuit 10A includes the amplifier 20, the first isolation impedance 22 at the INp input, and the second isolation impedance 24 at the INn input. The amplifier 20 and the isolation impedances 22 and 24 are similar to those shown in FIG. 2. The amplifier circuit 10A also includes a more particular example of the bias and protection circuit 30 shown in FIG. 2. The amplifier circuit 10A includes a bias circuit 32 and a breakdown protection circuit 34. The bias circuit 32 is configured to adjust a bias potential at the INp and INn inputs of the amplifier 20 with closed loop control based on the outputs of the amplifier 20. The bias circuit 32 is configured to adjust a bias potential at the inputs of the amplifier 20 for direct current interstage coupling in a multi-stage amplifier, in one example application. The breakdown protection circuit 34 is configured to maintain the collector to emitter voltage potential difference of the transistors Q1 and Q2 to within or below the breakdown voltage (i.e., the V_{CE} breakdown voltage) for the transistors Q1 and Q2, over a voltage supply range for the amplifier circuit. These and other aspects of the bias circuit 32 and the breakdown protection circuit 34 are described below.

The bias circuit 32 includes variable current sources 13 and 15, variable current sinks 14 and 16, and the differential amplifier 40. The operation of the variable current sinks 14 and 16 is similar to the operation of the variable current sources 13 and 15, as would be understood in the field, although the components are coupled in different ways. As used herein, the term variable current source can refer to either a current source or a current sink component unless otherwise specified. As shown in FIG. 3, the bias circuit 32 is coupled between the emitter terminal outputs of the transistors Q1 and Q2 and the INp and INn inputs of the amplifier circuit 10A. The bias circuit 32 is able to adjust the bias potentials at the base terminal inputs of the transistors Q1 and Q2 by charge sourcing or sinking with closed loop control. More particularly, the variable current sources 13 and 15 are arranged to source or inject charge to the base terminals of Q1 and Q2 based on control signals provided by the differential amplifier 40. The variable current sinks 14 and 16 are arranged to sink charge from the base terminals of Q1 and Q2 based on control signals provided by the differential amplifier 40.

The variable current source 13 is coupled between the upper rail voltage or potential V+ and the base terminal of the transistor Q1. The variable current sink 14 is coupled between the base terminal of the transistor Q1 and the lower rail voltage or potential V−. The variable current source 15 is coupled between the upper rail voltage or potential V+ and the base terminal of the transistor Q2. The variable current sink 16 is coupled between the base terminal of the transistor Q2 and the lower rail voltage or potential V−.

The variable current sources 13 and 15 and the variable current sinks 14 and 16 include control inputs. The operation of the current source 13 and the current sink 14 are directed or controlled by a first control signal provided from the differential amplifier 40 (e.g., at a non-inverting output) to the control inputs of the current source 13 and the current sink 14. The operation of the current source 15 and the current sink 16 are directed or controlled by a second control signal provided from the differential amplifier 40 (e.g., at an inverting output) to the control inputs of the current source 15 and the current sink 16.

The variable current sources 13 and 15 and the variable current sinks 14 and 16 are representative and can be implemented as any suitable types of current sources, sinks, or related charge pump or biasing circuits with control. Examples include transistor-based current mirrors and current regulators, including circuits that will generate a variable current output based on an applied bias voltage or other control signal. The variable current sources 13 and 15 and the variable current sinks 14 and 16 are not limited to any particular type of implementation.

The differential amplifier 40 can be embodied as a fully differential operational amplifier in one example. The differential amplifier 40 includes differential (i.e., dual) inputs and differential outputs in the example shown in FIG. 3. The inputs to the differential amplifier 40 include, at the non-inverting input, a first input potential coupled from the output emitter terminal of the transistor Q1 and, at the inverting input, a second input potential coupled from the output emitter terminal of the transistor Q2. The inputs to the differential amplifier 40 can be switched between the emitter terminals of the transistors Q1 and Q2, however. In any case, the differential amplifier 40 in the bias circuit 32 is configured to compare the voltages or potentials among or between the output emitter terminals of the transistors Q1 and Q2.

The output of the differential amplifier 40 is a differential signal provided across differential outputs of the differential amplifier 40. The outputs from the differential amplifier 40 include, at a non-inverting output, a first control signal provided to the variable current source 13 and the variable current sink 14. The outputs from the differential amplifier 40 also include, at an inverting output, a second control signal provided to the variable current source 15 and the variable current sink 16. In differential operation, the differential amplifier 40 is configured to direct the first and second control signals to reduce any difference in the bias voltages between the base terminals of the transistors Q1 and Q2, based on the potentials at the emitter terminals of the transistors Q1 and Q2.

The differential amplifier 40 controls the charge sourcing and sinking operations by the variable current sources 13 and 15 and the variable current sinks 14 and 16 based on the voltages or potentials at the emitter terminals of the transistors Q1 and Q2. The variable current sources 13 and 15 can be directed, at least in part, based on a difference in the voltages or potentials at the emitter terminals of the transistors Q1 and Q2. The variable current sinks 14 and 16 can also be directed, at least in part, based on the difference in the voltages or potentials at the emitter terminals of the transistors Q1 and Q2.

Current or charge sourced from the V+ upper rail and provided to the base of the transistor Q1 by the variable current source 13 will increase the bias voltage at the base of the transistor Q1. Similarly, current or charge sourced from the V+ upper rail and provided to the base of the transistor Q2 by the variable current source 15 will increase the bias voltage at the base of the transistor Q2. Current or charge sunk from the base of the transistor Q1 and provided to the V− lower rail by the variable current source 14 will decrease the bias voltage at the base of the transistor Q1. Similarly, current or charge sunk from the base of the transistor Q2 and provided to the V− lower rail by the variable current source 16 will decrease the bias voltage at the base of the transistor Q2.

Thus, the bias circuit 32 is configured to and capable of adjusting the bias potentials at the base terminals of the transistors Q1 and Q2 to a suitable operating bias point for the amplifier 20. When the amplifier 20 is implemented as one amplifier stage among several in a multi-stage amplifier, the bias circuit 32 is capable of altering or adjusting the bias potential (e.g., DC bias potential) of an input signal from a preceding stage to the operating bias point for the amplifier 20. The bias adjustment provided by the bias circuit 32 can compensate for the mismatch in bias potentials (e.g., DC bias potentials) at the INp and INn inputs, on one side of the isolation impedances 22 and 24, and that needed at the base terminals of the transistors Q1 and Q2 for the quiescent operating point of the amplifier 20.

The common-mode output voltage among the differential outputs of the differential amplifier 40 can also be controlled independently. In the example shown in FIG. 3, the common-mode output voltage on the differential outputs of the differential amplifier 40 is controlled by a common-mode reference input signal “Common.” A controller (not shown) can set the voltage or potential of the common-mode reference input signal for the differential operational amplifier 40. The common-mode reference input signal can be developed by an output of a digital-to-analog converter (DAC), for example, based on a digital input signal to the DAC provided from a controller, as one example.

The first isolation impedance 22 of the resistor Rp and the capacitor Cp serves to separate the potential at the INp input and the base terminal of the transistor Q1, so that the variable current source 13 and the variable current sink 14 can provide bias offset control. Similarly, the second isolation impedance 24 of the resistor Rn and the capacitor Cn serves to separate the potential at the INn input and the base terminal of the transistor Q2, so that the variable current source 15 and the current sink 16 can provide bias offset control. At high frequencies, the resistors Rp and Rn and the input impedances of the transistors Q1 and Q2 can limit the frequency response of the amplifier circuit 10A, particularly compared to the case without the resistors Rp and Rn. The capacitors Cp and Cn are added in parallel with the resistors Rp and Rn, to improve the frequency response of the amplifier circuit 10A. The resistances and capacitances of the resistors Rp and Rn and capacitors Cp and Cn can be selected based on design needs and the desired frequency response of the amplifier circuit 10A.

The breakdown protection circuit 34 includes a reference voltage generator in the current source 17 and the resistor R1, a level shifter in the current source 18 and the transistor Q3, and a regulator follower Q4. Based on the design of the breakdown protection circuit 34, the transistor Q3 can be embodied as a P-channel FET transistor, and the transistor Q4 can be embodied as an N-channel FET transistor in the example shown. The current source 17 and the resistor R1 are configured to generate a reference voltage at the “Ref” node, which can be selected based on the amount of current sourced by the current source 17 and the resistance of the resistor R1. The reference voltage at the “Ref” node can be selected by design and, as described below, controls the voltage output of the breakdown protection circuit 34 and the voltage at the collector terminals of the transistors Q1 and Q2 in the amplifier 20. The potential at the “Ref” node is provided to an input of the transistor Q3, which operates as a level shifter. In some cases, the current source 17 can be embodied as a variable current source, and the current source 17 can be controlled according to or based on the common-mode reference input signal provided to the differential amplifier 40. In that way, the potential at the “Ref” node can be made to track the common bias voltage changes applied by the bias circuit 32 to the base terminals of the transistors Q1 and Q2.

The transistor Q3 is relied upon to shift the voltage level of the “Ref” potential to a higher potential, because an output of the transistor Q3 is taken from the source of the transistor Q3. In other words, the output of the transistor Q3, taken from the source of the transistor Q3, is a shifted potential based on the “Ref” potential. The source of the transistor Q3 is coupled to the gate of the transistor Q4.

The transistor Q4 is arranged in the breakdown protection circuit 34 as a regulator follower. The output potential at the source of the transistor Q4 is based on the voltage at the gate of the transistor Q4, which is based on the voltage at the source of the transistor Q3 and the potential at the “Ref” node. Thus, the reference voltage at the “Ref” node can be selected by design and controls the voltage at the collector terminals of the transistors Q1 and Q2 in the amplifier 20. The transistor Q4 provides a regulated (i.e., constant) potential output for the amplifier 20, even over a range of different voltages of the V+ upper rail, according to the potential at the “Ref” node. The breakdown protection circuit 34 is thus configured to maintain the collector to emitter voltage potential difference to within or below the breakdown voltage (i.e., the V_{CE} breakdown voltage) for the transistors Q1 and Q2.

The transistors described herein, including the transistors Q1, Q2, Q3, and Q4, can be implemented as a range of different types of transistors formed in a range of different semiconductor materials. The transistors can be formed as bipolar junction transistors or FETs, and the concepts can be applied to a range of transistor types. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)—, gallium (Ga)—, indium (In)—, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlxGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{(1-a-b)}), among others. Typically, when present, arsenic and/or phosphorous are at low concentrations (e.g., less than 5 weight percent). The gallium nitride materials can be n-type doped, p-type doped, or unintentionally doped (UID).

In embodiments with high concentrations of gallium, gallium nitride material has a high concentration of gallium and includes little or no aluminum or indium. In high gallium concentration embodiments, the sum of (x+y) may be less than 0.4 in some cases, less than 0.2 in some cases, less than 0.1 in some cases, or even less in other cases. The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. An amplifier circuit with input biasing and breakdown protection comprising:
an amplifier comprising an input and an output;
a bias circuit coupled between the input and the output of the amplifier; and
a breakdown protection circuit coupled to a common terminal of the amplifier other than the input or the output, the breakdown protection circuit being configured to provide power to the amplifier based on a reference potential.

2. The amplifier circuit according to claim 1, wherein the breakdown protection circuit is configured to maintain a potential difference across the common terminal and the output of the amplifier based on the reference potential over a voltage supply range for the amplifier circuit.

3. The amplifier circuit according to claim 1, wherein:
the amplifier comprises a pair of common collector transistors; and
the breakdown protection circuit is coupled to collector terminals of the pair of common collector transistors.

4. The amplifier circuit according to claim 1, wherein the breakdown protection circuit comprises a reference voltage generator, a level shifter, and a regulator follower.

5. The amplifier circuit according to claim 1, wherein the bias circuit is configured to adjust a bias potential at the input of the amplifier with closed loop control based on the output of the amplifier.

6. The amplifier circuit according to claim 1, wherein:
the amplifier comprises a stage in a multi-stage amplifier; and
the bias circuit is configured to adjust a bias potential at the input of the amplifier for direct current interstage coupling in the multi-stage amplifier.

7. The amplifier circuit according to claim 1, wherein:
the amplifier comprises a stage in a multi-stage amplifier;
the amplifier circuit further comprises an isolation impedance coupled between a preceding amplifier stage in the multi-stage amplifier and the input of the amplifier; and
the isolation impedance comprises a parallel combination of a resistor and a capacitor.

8. The amplifier circuit according to claim 1, wherein the bias circuit comprises:
a variable current source coupled to the input of the amplifier; and
a differential amplifier coupled between the output of the amplifier and a control input of the variable current source.

9. The amplifier circuit according to claim 1, wherein:
the amplifier comprises a pair of transistors; and
the bias circuit comprises:
a first variable current source coupled to an input of a first transistor among the pair of transistors;
a second variable current source coupled to an input of a second transistor among the pair of transistors; and
a differential amplifier coupled between first and second outputs of the pair of transistors and control inputs of the first and second variable current sources.

10. An amplifier circuit comprising:
an amplifier comprising a pair of common collector transistors, an input, and an output;
a bias circuit coupled between the input and the output of the amplifier; and
a breakdown protection circuit coupled to a common terminal of the amplifier other than the input or the output, the breakdown protection circuit being configured to maintain a potential difference across the common terminal and the output of the amplifier based on a reference potential.

11. The amplifier circuit according to claim 10, wherein the breakdown protection circuit is coupled to collector terminals of the pair of common collector transistors.

12. The amplifier circuit according to claim 10, wherein the breakdown protection circuit comprises a reference voltage generator configured to generate the reference potential, a level shifter, and a regulator follower.

13. The amplifier circuit according to claim 10, wherein the bias circuit is configured to adjust a bias potential at the input of the amplifier with closed loop control based on the output of the amplifier.

14. The amplifier circuit according to claim 10, wherein:
the amplifier comprises a stage in a multi-stage amplifier; and
the bias circuit is configured to adjust a bias potential at the input of the amplifier for direct current interstage coupling in the multi-stage amplifier.

15. The amplifier circuit according to claim 10, wherein:
the amplifier comprises a stage in a multi-stage amplifier;
the amplifier circuit further comprises an isolation impedance coupled between a preceding amplifier stage in the multi-stage amplifier and the input of the amplifier; and
the isolation impedance comprises a parallel combination of a resistor and a capacitor.

16. The amplifier circuit according to claim 10, wherein the bias circuit comprises:
a first variable current source coupled to an input of a first transistor among the pair of common collector transistors;
a second variable current source coupled to an input of a second transistor among the pair of common collector transistors; and
a differential amplifier coupled between first and second outputs of the pair of common collector transistors and control inputs of the first and second variable current sources.

17. A biasing and breakdown protection circuit comprising:
a bias circuit coupled between an input and an output of an amplifier; and
a breakdown protection circuit configured to maintain a potential difference across terminals of the amplifier based on a reference potential.

18. The amplifier circuit according to claim 17, wherein the breakdown protection circuit comprises a reference voltage generator configured to generate the reference potential, a level shifter, and a regulator follower.

19. The amplifier circuit according to claim 17, wherein the bias circuit is configured to adjust a bias potential at the input of the amplifier with closed loop control based on the output of the amplifier.

20. The amplifier circuit according to claim 17, wherein the bias circuit comprises:
a first variable current source coupled to an input of a first transistor of the amplifier;
a second variable current source coupled to an input of a second transistor of the amplifier; and
a differential amplifier coupled between first and second outputs of the amplifier and control inputs of the first and second variable current sources.
